(19) United States
(12) Patent Application Publication
(10) Pub. No.: US 2026/0313797 A1
(43) Pub. Date: Oct. 8, 2026

(54) PRINTED CIRCUIT BOARD HAVING CONNECTION FINGERS PROVIDING IMPROVED ELECTRICAL CONTACT WITH CORRESPONDING SOCKET CONNECTION PINS UPON INSERTION

(71) Applicant: Micron Technology, Inc., Boise, ID (US)

(72) Inventor: Kolton T. Drake, Meridian, ID (US)

(21) Appl. No.: 19/576,610

(22) Filed: Mar. 24, 2026

Related U.S. Application Data
(60) Provisional application No. 63/783,303, filed on Apr. 4, 2025.

(51) Int. Cl. H05K 1/11; H05K 1/09

(52) U.S. Cl. CPC H05K 1/117; H05K 1/09; H05K 2201/10159

(57) ABSTRACT

Improved PCB assemblies and methods are described. An apparatus can include a board body and a plurality of connection fingers formed at an insertion edge of the board body. Each connection finger of the plurality of connection fingers comprises: a first portion configured to contact a respective connection pin upon insertion in a socket; and a second portion having an increased roughness as compared to the first portion.

### PRIORITY INFORMATION

This application claims the benefit of U.S. Provisional Application Number 63/783,303, filed on Apr. 4, 2025, the contents of which are incorporated herein by reference.

### TECHNICAL FIELD

The present disclosure relates generally to printed circuit board (PCB) assemblies, and more specifically to PCBs having connection fingers providing improved electrical contact with corresponding socket connection pins upon insertion.

### BACKGROUND

Computing systems often include memory modules in the form of printed circuit board (PCB) assemblies that include a number of memory devices coupled to one or both sides. One example of a memory module is a dual in-line memory module (DIMM) that can include a number of dynamic random access memory (DRAM) chips. The memory modules can be coupled to a system motherboard by being inserted into a receiving slot or “socket.” Each memory module includes a plurality of connection fingers on its insertion edge surface that are configured to electrically couple to a corresponding terminal (e.g., connection pin) within the socket. The connection fingers are commonly referred to as “gold fingers.” Various memory modules can have different quantities of connection fingers (e.g., 72, 100, 168, 200, 244, 262), which can depend on module type and/or particular memory standard (e.g., JEDEC standard).

Ensuring proper electrical contact between the connection fingers of a memory module and the corresponding connection pins of the socket is important in order to provide proper functioning of the computing system. Improper electrical contact upon insertion of a memory module into a socket can lead to drawbacks such as multiple retests and/or failed testing, which can result in a memory module being incorrectly determined to be “bad” (e.g., non-functional).

### BRIEF DESCRIPTION OF THE DRAWINGS

FIG. 1 illustrates a PCB in the form of a memory module having connection fingers configured to provide improved electrical contact with corresponding socket connection pins upon insertion in accordance with a number of embodiments of the present disclosure.

FIG. 2A illustrates a portion of a PCB having connection fingers in accordance with various embodiments of the present disclosure.

FIG. 2B is a cross-sectional view of FIG. 2A.

FIG. 2C is a zoomed in view of an example connection finger in accordance with various embodiments of the present disclosure.

FIG. 3A illustrates a socket prior to having a PCB in accordance with embodiments of the present disclosure inserted therein.

FIG. 3B illustrates the socket shown in FIG. 3A during insertion of a PCB in accordance with embodiments of the present disclosure.

FIG. 3C illustrates the socket shown in FIG. 3A once a PCB in accordance with embodiments of the present disclosure has been fully inserted.

FIG. 4 is a block diagram of a computing system including a PCB in accordance with a number of embodiments of the present disclosure.

### DETAILED DESCRIPTION

The present disclosure relates generally to printed circuit board (PCB) assemblies, and more specifically to PCBs having connection fingers providing improved electrical contact with corresponding socket connection pins upon insertion.

PCB assemblies, such as memory modules (e.g., DIMMs, SO-DIMMs, etc.), s, graphics cards, etc., often include connections fingers, which may be referred to as “gold fingers” or “edge connectors.” The connection fingers can serve to electrically connect a PCB to another PCB via a socket. For example, connection fingers on a memory module can be inserted into a socket of a motherboard or peripheral device.

Ensuring proper and reliable electrical contact between connection fingers and corresponding socket pins is desirable. Accordingly, it can be beneficial to provide connection fingers having a relatively smooth surface, which can provide improved electrical performance (e.g., via reduced contact resistance), improved durability (e.g., by reducing accumulation of dust and oxides on a rough surface), and/or can reduce the likelihood of mechanical damage to socket pins, which can be scratched by a rough surface of a connection finger. As such, gold fingers can be manufactured in compliance with various standards (e.g., JEDEC, IPC, etc.).

Various PCBs, such as DIMMs, can experience an insertion failure in which the DIMM fails to function properly after insertion (e.g., into a socket). Failures that occur during an initial boot-up or training process can be referred to as “first insertion failures.” Such insertion failures can be caused, for example, by surface contamination on the gold fingers, contamination on the socket pins, and/or bent/broken socket pins. As such, even if a DIMM is perfectly functional, contamination on the socket pins can prevent proper electrical contact between the socket pins and corresponding gold fingers. Socket pin contamination can come in the form of debris such as dust and/or oxide formed on the portions of the pins configured to make contact with the corresponding gold fingers. In instances in which socket pin contamination results in a first insertion failure, removing the DIMM and re-inserting it can often remedy the failure. Although first insertion failures can be relatively infrequent, it is desirable to reduce the frequency of their occurrence to improve customer experience, reduce test time, etc.

Various embodiments of the present disclosure provide gold fingers having an improved morphology that can reduce insertion failure rates associated with PCBs (e.g., memory modules) on which they are formed. Various embodiments include gold fingers having a portion with an increased surface roughness (e.g., average roughness (Ra)) as compared to a remaining portion. The rougher portion can be nearer to the insertion edge of the PCB such that it contacts a corresponding socket pin during insertion, with the roughened surface providing a “cleaning” effect by removing debris from the socket pin as it passes by. The cleaning of the socket pin via the roughened portion of the gold finger helps to ensure a good/effective electrical contact between the socket pin and the remaining portion (e.g., the smoother portion) of the gold finger. In various embodiments, the gold fingers of the present disclosure can be compliant with a particular standard such as a JEDEC standard. .

In the following detailed description of the present disclosure, reference is made to the accompanying drawings that form a part hereof, and in which is shown by way of illustration, how a number of embodiments of the disclosure may be practiced. These embodiments are described in sufficient detail to enable those of ordinary skill in the art to practice the embodiments of this disclosure, and it is to be understood that other embodiments may be utilized and that process, electrical, and/or structural changes may be made without departing from the scope of the present disclosure.

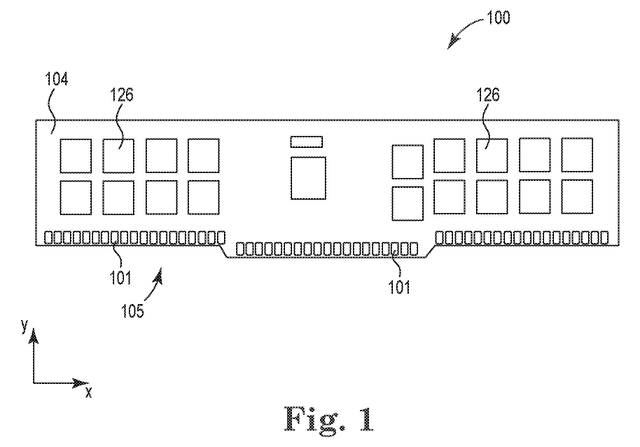

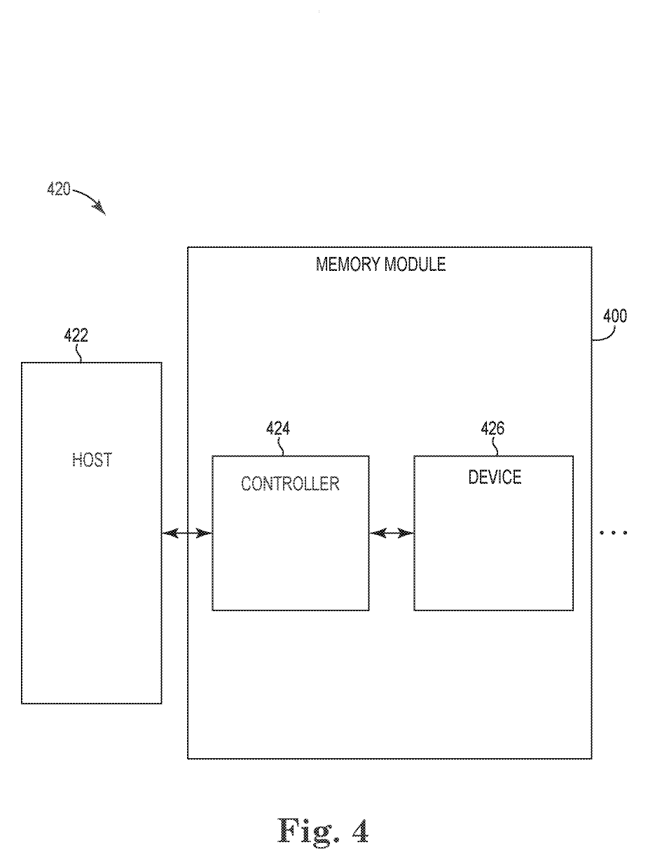

As used herein, “a number of” something refers to one or more of such things. For example, a number of memory devices can refer to one or more memory devices. The figures herein follow a numbering convention in which the first digit or digits correspond to the drawing figure number and the remaining digits identify an element or component in the drawing. Similar elements or components between different figures may be identified by the use of similar digits. For example, “126” can identify element 26 in FIG. 1, and a similar element can be labelled “426” in FIG. 4. As will be appreciated, elements shown in the various embodiments herein can be added, exchanged, and/or eliminated so as to provide a number of additional embodiments of the present disclosure. In addition, the proportion and the relative scale of the elements provided in the figures are intended to illustrate various embodiments of the present disclosure and are not to be used in a limiting sense.

FIG. 1 illustrates a PCB 100 in the form of a memory module having connection fingers configured to provide improved electrical contact with corresponding socket connection pins upon insertion in accordance with a number of embodiments of the present disclosure. As an example, the PCB 100 can be a DIMM having a board body 104 to which a number of memory devices 126 (e.g., DRAM chips) are coupled. Although not described in detail, the PCB 100 can include various other components coupled thereto (e.g., a memory controller, interfaces, power management ICs, clocking circuitry, timing circuitry, etc.).

The PCB 100 includes an insertion edge 105 on which a plurality of connection fingers (e.g., gold fingers) 101 are formed. The memory devices 126 and other components of the PCB 100 receive electrical signals from external components (e.g., host processor) via the gold fingers 101.

The particular physical configuration of the PCB 100 can depend on various factors. For instance, the PCB 100 may conform to a particular standard (e.g., JEDEC standard). Accordingly, the physical characteristics of the PCB 100 such as height, width, and/or quantity and/or placement of connection fingers 101 (e.g., pitch) can be in accordance with a particular standard and/or protocol (e.g., DDR2, DDR3, DDR4, DDR5, etc.).

As described further herein below, in various embodiments, a surface of the connection fingers 101 has a non-uniform roughness. For example, each connection finger can comprise a portion having an increased surface roughness as compared to a remaining portion. The rougher portion can be located closer to the insertion edge of the PCB and can serve to “clean” a surface of a socket pin during insertion of the PCB into a socket. The smoother portion of the connection finger is configured to provide physical electrical contact with the corresponding socket pin once the PCB is fully inserted into the socket. Adjusting the surface morphology (e.g., “roughness”) of the rougher portion of the connection finger can be accomplished in various manners. For example, the roughening can occur via a mechanical stamping process, a mechanical scoring process, an abrasive blasting process, and/or an electrochemical etching process.

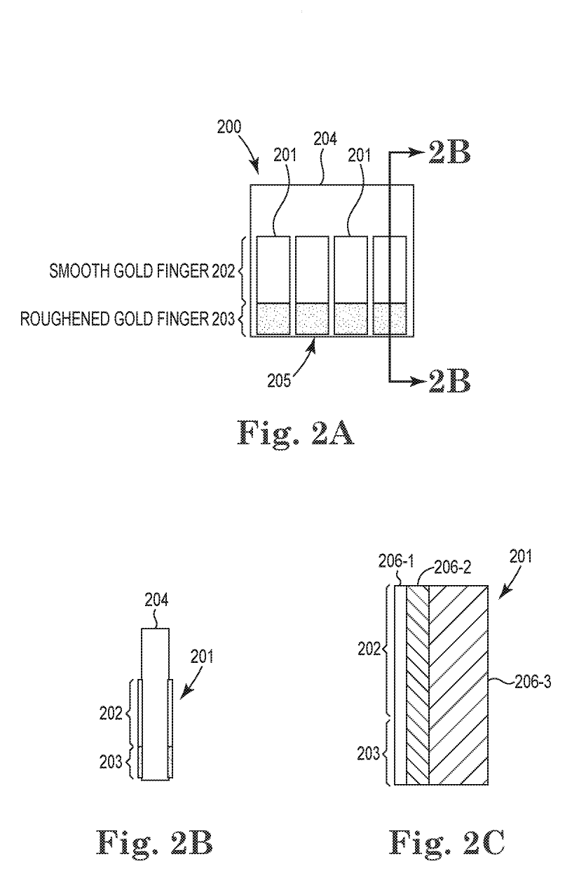

FIG. 2A illustrates a portion of a PCB 200 having connection fingers 201 in accordance with various embodiments of the present disclosure. FIG. 2B is a cross-sectional view of FIG. 2A.

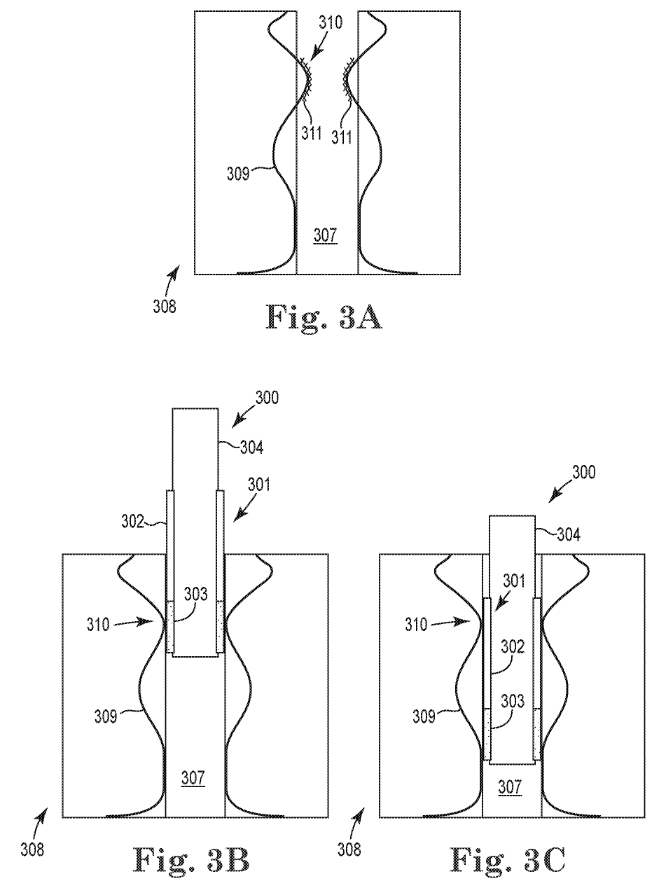

The PCB 200 can be a PCB such as PCB 100 described in FIG. 1. The connection fingers 201 are located at an insertion edge 205 of the board body 204. As shown in FIG. 2B, the connection fingers 201 can be formed on both sides of the board body 204, such as is the case for DIMMs. The connection fingers 201 include a portion 202 configured to directly contact respective corresponding socket pins when the PCB 200 is fully inserted into a receiving slot of a socket, and a portion 203 having a rougher surface as compared to the portion 202. The roughened portion 203 is configured to remove debris (e.g., dust, oxide, Carbon, Oxygen, Silicon, etc.) from the surface of the corresponding socket pin during insertion of the PCB 200 into the socket. Interaction of the connection fingers 201 with corresponding socket pins is described further in association with FIGS. 3A-3C. In various embodiments, the smooth portion 202 has an average roughness Ra of 0.2 microns or less.

A length of the smooth portion 202 compared to the roughened portion 203 can vary. For example, in some embodiments, the portion 203 can be about 1/4 to 1/3 of a total length of the connection finger 101. However, embodiments are not so limited. For example, in some instances, the roughened portion may be about 1/8 of a total length of the connection finger 201.

In various embodiments, the surface of the connections fingers 201 comprise Gold (Au); however, embodiments are not limited to a particular conductive material type. In various embodiments, the connection fingers 201 can comprise multiple material layers (e.g., an outermost/top/uppermost material layer and a number of underlying material layers). For example, as illustrated in FIG. 2C, which is a zoomed in view of a connection finger 201, the connection fingers can comprise an outermost material layer 206-1 configured to physically contact the corresponding socket pins, a first underlying material layer 206-2, and a second underlying material layer 206-3, which can be a bottom/base material layer. As an example, the top layer 206-1 can be an Au layer, the layer 206-2 can be a Nickel (Ni) or Cobalt (Co) layer, and the layer 206-3 can be a Copper (Cu) layer. For instance, embodiments can include a Au layer of about 1 micron, an underlying Ni layer 206-2 of about 2.5 to 10 microns, and a base Cu layer 206-3 of about 40 to 50 microns.

In various embodiments, the difference in roughness between portion 203 and portion 202 can be a threshold amount such as at least 0.3 microns Ra (arithmetic mean roughness or average roughness), at least 0.2 microns, at least 0.25 microns Ra, at least 0.5 microns Ra, etc. The roughness difference can be, for example, between 0.3 microns Ra and 0.6 microns Ra. The roughness values can be measured via various tools such as a profilometer or laser scanner, for instance. Other roughness measurements can be used. For example, a root mean square roughness (Rq) can be used.

FIG. 3A illustrates a socket 308 prior to having a PCB in accordance with embodiments of the present disclosure inserted therein. FIG. 3B illustrates the socket 308 shown in FIG. 3A during insertion of a PCB 300 in accordance with embodiments of the present disclosure. FIG. 3C illustrates the socket 308 shown in FIG. 3A once a PCB 300 in accordance with embodiments of the present disclosure has been fully inserted.

The socket 308 can be located, for example, on a motherboard or other PCB. As illustrated in FIG. 3A, the socket 308 includes a receiving slot 307 into which a PCB 300 having gold fingers 301 thereon can be inserted. The PCB 300 can be a PCB such as PCB 100 shown in FIG. 1 or PCB 200 shown in FIGS. 2A-2C. Accordingly, the PCB 300 includes a board body 304 having connection fingers 301 formed thereon.

The socket 308 comprises a socket connection pin 309. The connection pin 309 includes a portion 310 that protrudes into the receiving slot 307 and is configured to make physical and electrical contact with a corresponding gold finger 301 upon insertion of the PCB 300. Upon insertion of the PCB 300, the portion 310 of the pin 309 is pushed out of the slot 307 via a cantilever action as shown in FIGS. 3B and 3C.

As illustrated in FIG. 3A, an amount of debris 311 can accumulate on the portion 310 of the socket pin 309. Such debris 311 can include, for example, various types of dust and/or oxides that can be relatively high impedance materials that adversely affect the electrical connection between the pin portion 310 and the corresponding gold finger 301.

In various embodiments, and as illustrated in FIG. 3B, a roughened portion 303 of a gold finger 301 can remove such debris 311 from portion 310 of pin 309 as it traverses into the slot 307. For instance, the friction between the portion 303 and portion 310 serves to “clean” the portion 310. In previous approaches in which the entire finger 301 is smooth, such smooth surface beneficially provides a more effective electrical connection with the socket pin (as compared to a rougher gold finger surface); however, the smoother finger surface does not as effectively remove the debris 311 from pin portion 310, which can lead to issues such as first insertion failures.

FIG. 3C illustrates the PCB 300 fully inserted into slot 307 of socket 308. As shown, the debris 311 has been removed from the pin portion 310 via the roughened portion 303 of the finger 301. The smooth portion 302 of the finger 301 is in physical and electrical contact with the portion 310 of pin 309.

FIG. 4 is a block diagram of a computing system 420 including a PCB 400 in accordance with a number of embodiments of the present disclosure. The system 420 includes a host 422 coupled to the PCB 400, which can be a PCB such as PCB 100 shown in FIG. 1, PCB 200 shown in FIGS. 2A-2C, or PCB 300 shown in FIGS. 3B-3C. In this example, the PCB 400 is a memory module, which can be a DIMM comprising a number of memory devices (e.g., DRAM devices) 426 and a controller 424.

The system 420 can be, or can be part of, for example, a desktop computer, laptop computer, television, home theater system, gaming console, digital camera, network router and/or switch, printer, scanner, medical device, GPS navigation device, home device (e.g., thermostat, doorbell camera, security camera, smart lock, etc.), wearable device, industrial control system (e.g., automated industrial and/or control device) mobile computing device, a vehicle (e.g., airplane, drone, train, automobile, or other conveyance), Internet of Things (IoT) enabled device, embedded computer (e.g., one included in a vehicle, industrial equipment, or a networked commercial device), SoC, chipset (e.g., a collection of integrated circuits), tile, Field-Programmable Gate Array (FPGA) structure (e.g., segmented FPGA structure), or another such device.

The host 422 can include a processor chipset and a software stack executed by the processor chipset. For example, the host 422 can be, or can include, a central processing unit (CPU) or a CPU complex that can be configured to execute an operating system.

The host 422 can be coupled to the memory module 400 via a physical and/or logical host interface that operates based on various communication protocols and to provide control, address, data, and other signals to the controller 424 (e.g., to further cause the controller 424 to control the device 426). Examples of the interface between the host 422 and the memory module 400 can include, but not limited to, a bus interface (e.g., a serial advanced technology attachment (SATA) interface, a Serial Attached SCSI (SAS) interface, a Serial Attached SCSI (SAS) interface, a Small Computer System Interface (SCSI), a peripheral component interconnect express (PCIe) interface, ISA, etc.), a memory interface (e.g., a double data rate (DDR) interface, a dual in-line memory module (DIMM) interface, an Open NAND Flash Interface (ONFI) interface, an NVM Express (NVMe) interface), a Fibre Channel, an UART interface, an I2C interface, a Serial Peripheral Interface (SPI), an Universal Serial Bus (USB) interface, an ethernet interface, a general-purpose input/output (GIPO) interface, a custom interface, etc.

Although not shown in FIG. 4, the controller 424 can include a processing device (e.g., processor ) that can execute instructions stored in a local memory to perform various operations. The controller 424 can include various special purpose circuitry in the form of an ASIC, FPGA, state machine, and/or other logic circuitry.

Although specific embodiments have been illustrated and described herein, those of ordinary skill in the art will appreciate that an arrangement calculated to achieve the same results can be substituted for the specific embodiments shown. This disclosure is intended to cover adaptations or variations of different embodiments of the present disclosure. It is to be understood that the above description has been made in an illustrative fashion and not a restrictive one. A combination of the above embodiments, and other embodiments not specifically described herein will be apparent to those of skill in the art upon reviewing the above description. The scope of the various embodiments of the present disclosure includes other applications in which the above structures and methods are used. Therefore, the scope of various embodiments of the present disclosure should be determined with reference to the appended claims, along with the full range of equivalents to which such claims are entitled.

In the foregoing Detailed Description, various features are grouped together in a single embodiment for the purpose of streamlining the disclosure. This method of disclosure is not to be interpreted as reflecting an intention that the disclosed embodiments of the present disclosure have to use more features than are expressly recited in each claim. Rather, as the following claims reflect, inventive subject matter lies in less than all features of a single disclosed embodiment. Thus, the following claims are hereby incorporated into the Detailed Description, with each claim standing on its own as a separate embodiment.

What is claimed is:

1. An apparatus, comprising;
a board body; and
a plurality of connection fingers formed at an insertion edge of the board body; and
wherein each connection finger of the plurality of connection fingers comprises:
a first portion configured to contact a respective connection pin upon insertion in a socket; and
a second portion having an increased roughness as compared to the first portion.

2. The apparatus of claim 1, wherein the second portion is located closer to the insertion edge of the board body than the first portion.

3. The apparatus of claim 2, wherein the first portion and the second portion comprise portions of a Gold (Au) layer.

4. The apparatus of claim 1, wherein the increased roughness of the second portion as compared to the first portion is at least 0.3 microns arithmetic mean roughness (Ra).

5. The apparatus of claim 4, wherein the first portion has an arithmetic mean roughness (Ra) of 0.2 microns or less, and wherein the increased roughness of the second portion as compared to the first portion is between 0.3 microns and 0.6 microns Ra.

6. The apparatus of claim 1, wherein each connection finger of the plurality of connections fingers comprises multiple material layers including an uppermost material layer and an adjacent underlying material layer, and wherein the uppermost material layer comprises the first portion and the second portion.

7. The apparatus of claim 6, wherein the adjacent underlying material layer comprises Nickel (Ni), or Cobalt (Co), or both.

8. The apparatus of claim 1, wherein the apparatus is a dual in-inline memory module (DIMM).

9. A method of forming a memory module including,
forming a plurality of connection fingers at an insertion edge of a board body; and
adjusting a morphology of a portion of each of the plurality of connection fingers such that a roughness of the portion of each of the plurality of connection fingers is greater, by at least a threshold amount, than a roughness of a remaining portion of each of the plurality of connection fingers.

10. The method of claim 9, wherein adjusting the morphology of the portion of each of the plurality of connection fingers comprises performing a mechanical scoring process on the portion of each of the plurality of connection fingers.

11. The method of claim 9, wherein adjusting the morphology of the portion of each of the plurality of connection fingers comprises performing an electrochemical etching process on the portion of each of the plurality of connection fingers.

12. The method of claim 9, wherein adjusting the morphology of the portion of each of the plurality of connection fingers comprises performing a stamping process on the portion of each of the plurality of connection fingers.

13. The method of claim 9, wherein adjusting the morphology of the portion of each of the plurality of connection fingers comprises performing an abrasive blasting process on the portion of each of the plurality of connection fingers.

14. The method of claim 9, wherein forming the plurality of connection fingers comprises:
forming an underlying Copper (Cu) material layer;
forming a Nickel (Ni) material layer on the Copper material layer; and
forming a Gold (Au) material layer on the Ni material layer; and
wherein the threshold amount of roughness is at least 0.2 microns.

15. The method of claim 9, wherein the threshold amount of roughness is between 0.1 microns and 0.5 microns arithmetic mean roughness (Ra).

16. An apparatus, comprising:
a socket comprising a plurality of connection pins; and
a memory module comprising a board body and a plurality of connection fingers formed on an insertion edge of the board body and configured to provide an electrical connection with respective connection pins of the plurality of connection pins upon insertion into the socket; and
wherein each connection finger of the plurality of connection fingers comprises:
a first underlying material layer; and
an uppermost material layer formed on the first underlying material layer;
wherein a surface of the uppermost material layer has a non-uniform roughness;
wherein a roughness of a first portion of the uppermost material layer is greater than a roughness of a second portion of the uppermost material layer; and wherein the first portion is located closer to the insertion edge than the second portion.

17. The apparatus of claim 16, wherein:
the second portion is configured to be in physical contact with a corresponding one of the respective connection when the memory module is fully inserted into the socket; and
the first portion is configured to not be in physical contact with the corresponding one of the respective connection pins when the memory module is fully inserted into the socket.

18. The apparatus of claim 16, wherein the first portion is a stamped portion of the uppermost material layer, and the second portion is a non-stamped portion of the uppermost material layer.

19. The apparatus of claim 16, wherein each connection finger of the plurality of connection fingers comprises a second underlying material layer on which the first underlying material layer is formed, wherein the first underlying material comprises Nickel (Ni) and the second underlying material comprises Copper (Cu).

20. The apparatus of claim 16, wherein the first portion of the uppermost material layer is a cleaning portion, and wherein the roughness of the first portion is at least 0.4 microns (Ra = 0.4).
